(19) United States
(12) Patent Application Publication
(10) Pub. No.: US 2007/0218624 A1
(43) Pub. Date: Sep. 20, 2007

(54) Semiconductor device and method of manufacturing the same

(75) Inventors: Hideki Satake, Chigasaki-shi (JP); Toshihide Nabatame, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignees: KABUSHIKI KAISHA TOSHIBA; Renesas Technology Corp.

(21) Appl. No.: 11/724,247

(22) Filed: Mar. 15, 2007

(30) Foreign Application Priority Data
Mar. 17, 2006 (JP) 2006-075570

(51) Int. Cl. H01L 21/8242

(52) U.S. Cl. 438/240

(57) ABSTRACT

A method of manufacturing an MIS semiconductor device includes forming a high dielectric film as a gate insulator on a semiconductor substrate of a first conductivity type, heat-treating the semiconductor substrate in ambient with hydrogen and oxygen gases to form an interface layer between the semiconductor substrate and the high dielectric film, forming a conductive film on the high dielectric film after the interfacial layer is formed, processing the conductive film in a gate pattern to form a gate electrode, and doping the semiconductor substrate with impurities of a second conductivity type using the gate electrode as a mask to form source/drain regions.

### CROSS-REFERENCE TO RELATED APPLICATIONS

This application is based upon and claims the benefit of priority from prior Japanese Patent Application No. 2006-075570, filed Mar. 17, 2006, the entire contents of which are incorporated herein by reference.

### BACKGROUND OF THE INVENTION

1. Field of the Invention

The present invention relates to a semiconductor device having a metal-insulator-semiconductor (MIS) structure which is improved in gate insulating film, and a method of manufacturing the same.

2. Description of the Related Art

MOS transistors have recently decreased in size in order to increase the performance and speed of a large-scale integrated circuit (LSI). Accordingly, the gate insulating films of the MOS transistors have suddenly decreased in thickness. In conventionally-used silicon oxide films (SiO₂), an enormous amount of gate leakage current flows. Gate insulating films are therefore strongly required for the silicon oxide films (SiO₂). Under these circumstances, it is tried to reduce gate leakage current using high dielectric constant materials, whose dielectric constant is higher than that of SiO₂, for a gate insulating film to thicken the physical thickness of the gate insulating film.

A serious problem in forming the above high dielectric film (what is called a High-k film) is that an interface layer whose quality is low and dielectric constant is low is formed in the interface between the high dielectric film and a silicon (Si) substrate when the high dielectric film is formed by normal techniques. The main object of using a high dielectric film is to obtain the advantage that its dielectric constant is high. The interfacial layer of low dielectric constant brings about a fatal disadvantage that the thickness of a gate insulating film converted to SiO₂ (EOT) cannot be decreased.

In a normal manufacturing process, a method of forming an interfacial layer of, e.g., SiO₂ on a silicon substrate and then forming a high dielectric gate insulating film on the interfacial layer is employed. This method has a serious problem that process damage is caused to the interfacial layer in a step of forming the gate insulating film and the gate insulating film is deteriorated in a step of manufacturing a transistor.

An annealing method using He gas (JP-A 2003-297829 (KOKAI)) and an annealing method using heavy hydrogen (D2) (JP-A 2005-166929 (KOKAI)) are proposed as one to resolve the above problem. However, neither of the methods brings about any advantage of retarding the growth of an interfacial layer though the methods contribute to high reliability of a gate insulator.

As described above, conventionally, when a high dielectric film is formed as a gate insulator, a low dielectric interfacial layer is inevitably formed at interface between the high dielectric film and a silicon substrate. The advantage of high dielectric constant, which is obtained by the use of the high dielectric film, cannot be enjoyed sufficiently. Further, in order to inhibit the deterioration of mobility of electrons, a high dielectric film is generally formed after a thin SiO₂ film is formed in advance. However, the SiO₂ film is directly subjected to process damage in forming a subsequent high dielectric film and performing heat treatment for activating impurities. It is therefore very difficult to form a thin interfacial SiO₂ layer with stability.

### BRIEF SUMMARY OF THE INVENTION

An object of the present invention is to provide a semiconductor device in which an interfacial layer of good quality can be formed between a high dielectric gate insulating film and a semiconductor substrate to enjoy the advantage obtained from the use of the high dielectric gate insulating film.

According to an embodiment of the present invention, there is provided a method of manufacturing an MIS semiconductor device, comprising forming a high dielectric film as a gate insulator on a semiconductor substrate of a first conductivity type, forming an interfacial layer between the semiconductor substrate and the high dielectric film by heat-treating the semiconductor substrate in an atmosphere containing hydrogen gas and oxygen gas, forming a conductive film on the high dielectric film after the interfacial layer is formed, forming a gate electrode by processing the conductive film to have a gate pattern, and forming source/drain regions by doping the semiconductor substrate with impurities of a second conductivity type using the gate electrode as a mask.

According to another embodiment of the present invention, there is provided a method of manufacturing an MIS semiconductor device, comprising forming a high dielectric film as a gate insulator on a semiconductor substrate of a first conductivity type, forming a conductive film on the high dielectric film, forming a gate electrode by processing the conductive film to have a gate pattern, forming an interface layer between the semiconductor substrate and the high dielectric film by heat-treating the semiconductor substrate with the gate electrode in an atmosphere containing hydrogen gas and oxygen gas, and forming source/drain regions by doping the semiconductor substrate with impurities of a second conductivity type using the gate electrode as a mask, after the interfacial layer is formed.

According to still another embodiment of the present invention, there is provided a method of manufacturing an MIS semiconductor device, comprising forming a high dielectric film as a gate insulator on a semiconductor substrate of a first conductivity type, forming a conductive film on the high dielectric film, forming a gate electrode by processing the conductive film to have a gate pattern, forming a sidewall insulation film on either side of the gate electrode, forming an interfacial layer between the semiconductor substrate and the high dielectric film by heat-treating the semiconductor substrate with the gate electrode and the sidewall insulating film in an atmosphere containing hydrogen gas and oxygen gas, and forming source/drain regions by doping the semiconductor substrate with impurities of a second conductivity type using the gate electrode and the sidewall insulation film as masks, after the interface layer is formed.

According to yet another embodiment of the present invention, there is provided a MIS semiconductor device comprising a semiconductor substrate of a first conductivity type, a gate electrode formed on the semiconductor substrate with a high dielectric gate insulating film therebetween, and source/drain regions of a second conductivity type, which are formed on a surface of the semiconductor substrate and between which a channel region is formed under the gate electrode, wherein the gate insulating film has an oxygen density profile that is controlled such that a differential value of oxygen density of the gate insulating film is zero or more in a thickness direction of the gate insulating film in a region located at a distance of 0.5 nm or more from an interface between the gate electrode and the gate insulating film and in a region located at a distance of 0.3 nm or more from an interface between the semiconductor substrate and the gate insulating film.

### BRIEF DESCRIPTION OF THE SEVERAL VIEWS OF THE DRAWING

FIG. 1 is a schematic cross sectional view of the structure of an MIS semiconductor device according to the first embodiment;

FIGS. 2A to 2D are cross sectional views showing a process of manufacturing the MIS semiconductor device according to the first embodiment;

FIG. 3A shows a cross sectional TEM photograph of the crystal structure of a gate electrode section obtained when an interfacial layer is formed according to the first embodiment;

FIG. 3B shows a cross sectional TEM photograph of the crystal structure of a gate electrode section obtained when an interfacial layer is formed according to a prior art method;

FIG. 4 shows a graph of variations of the interface state density Dit, S factor, and silicon-oxide-film equivalent oxide thickness (EOT) in an nMISFET when the temperature of processing varies;

FIG. 5 shows a graph of effective field dependency of electron mobility in the nMISFET when the temperature of processing varies;

FIG. 6A is a diagram showing a profile of oxygen density in a gate insulating film;

FIG. 6B shows a graph of a differential value of the oxygen density in the gate insulating film;

FIG. 7 is a schematic cross sectional view of an MIS semiconductor device according to the second embodiment; and

FIGS. 8A to 8D are cross sectional views showing a process of manufacturing the MIS semiconductor device according to the second embodiment.

### DETAILED DESCRIPTION OF THE INVENTION

Embodiments of the present invention will be described in detail with reference to the accompanying drawings.

### First Embodiment

FIG. 1 shows a cross sectional view of an MIS semiconductor device, taken in the direction of the channel length of the device.

Referring to FIG. 1, element isolation regions 11 and 12 are formed to a depth of about 0.6 μm in the surface area of a p-type silicon substrate 10 of face orientation (100) so as to surround an element forming region. An interfacial layer 13b having a thickness of e.g., 0.3 nm to 1 nm is formed on part of the element forming region, and a high dielectric gate insulating film 13a that is made of, e.g., HfSiON is deposited thereon. The interface layer 13b is formed by depositing the high dielectric gate insulating film 13a and then exposing the surface of the silicon substrate 10 to an atmosphere containing H₂ gas and O₂ gas and ranging from 0.2 Torr to 2000 Torr for heat treatment.

A nickel silicide film having a thickness of 80 nm is formed on the high dielectric gate insulating film 13a as a gate electrode 14. A sidewall insulating film 17 of, e.g., a silicon nitride film is formed on either side of the gate electrode 14. Source/drain extension layers (n⁻ layers) 15 and 16 are formed in the surface area of the substrate and on the undersurface of the sidewall insulating film 17. Source/drain diffusion layers (n⁺ layers) 18 and 19 are formed in the surface area of the substrate and outside the source/drain extension layers 15 and 16. A titanium silicide film (not shown) is formed on the surface of each of the source/drain diffusion layers 18 and 19.

A silicon oxide film 20 is formed as an interlayer insulation film on the entire surface of the substrate with the gate electrode 14 and sidewall insulating film 17 thereon. Contact holes are formed in the interlayer insulation film 20 in positions corresponding to the gate electrode 14 and source/drain diffusion layers 18 and 19. Aluminum-electrodes 21, 22 and 23 are so formed that they are connected to the gate electrode 14 and source/drain diffusion layers 18 and 19 via the contact holes.

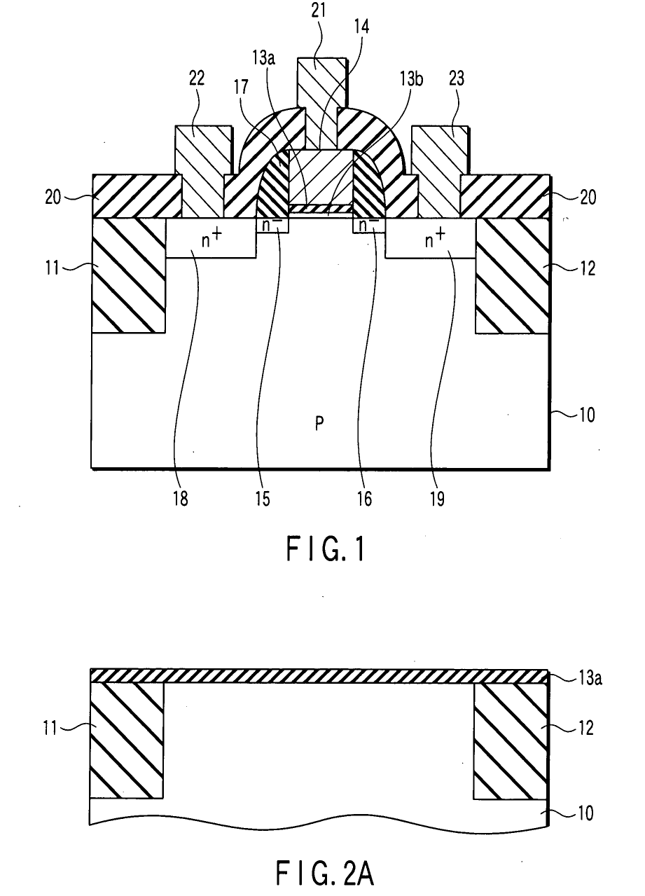

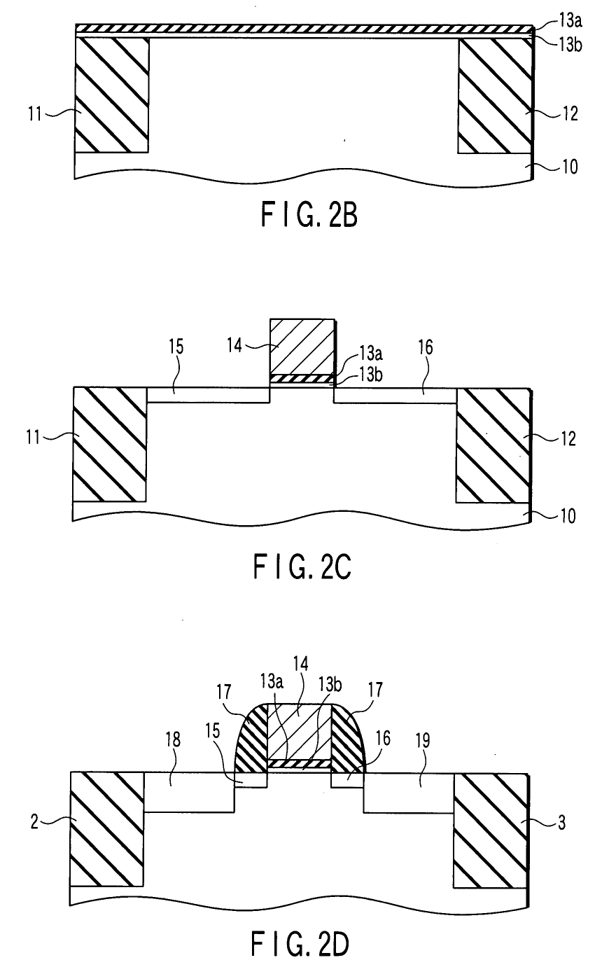

A process of manufacturing the MIS semiconductor device according to the first embodiment will be described in FIGS. 2A to 2D.

As shown in FIG. 2A, a p-type silicon substrate 10 of, e.g., face orientation (100) is prepared, and element isolation regions 11 and 12 are formed to a depth of about 0.6 μm in the surface area of the p-type silicon substrate 10 by a normal shallow trench isolation (STI) method. For example, a silicon oxide film is buried into the element isolation regions 11 and 12. After that, a diluted fluorinated acid process is performed in concentrations of, e.g., 1% and then a high dielectric gate insulation film 13a containing hafnium atoms, oxygen atoms and nitrogen atoms is deposited by a layer-by-layer deposition and annealing (LL-D&A) method using, e.g., NH₃ gas.

And then, as shown in FIG. 2B, wet oxidation is performed by exposing the substrate with the high dielectric gate insulating film 13a to the atmosphere containing H₂ gas and O₂ gas for only five seconds at a temperature of 1000° C. and at pressure of 10 Torr. The interfacial layer 13b is thus formed between the gate insulating film 13a and the silicon substrate 10. As the conditions for the above heat treatment, it is desirable that the temperature range from 800° C. to 1100° C., the pressure range from 0.2 Torr to 200 Torr, the time range from 1 second to 10 seconds.

As shown in FIG. 2C, a nickel silicide film is formed on the gate insulating film 13a as the gate electrode 14. More specifically, an amorphous silicon film having a thickness of 50 nm and a nickel film having a thickness of 30 nm are deposited and then these films are exposed to the atmosphere of nitrogen gas for ten seconds to one hour at a temperature of 400° C. to 700° C. to form a nickel silicide film. After that, using a resist mask not shown, the nickel silicide film, gate insulating film 13a and interfacial layer 13b are continuously etched by reactive ion etching, thus forming the gate electrode 14. Using the gate electrode 14 as a mask, arsenic (As) is ion-implanted into the surface of the silicon substrate 10 under the conditions that an acceleration voltage is 1 keV to 10 keV and a dose is 1×10¹⁴ cm⁻², thus forming first impurity diffusion regions (source/drain extension layers) 15 and 16.

As shown in FIG. 2D, a sidewall insulation film 17 is formed on either side of the gate electrode 14. More specifically, the resist mask is removed and then a silicon nitride film having a thickness of, e.g., 10 nm is deposited using low-pressure chemical vapor deposition (LP-CVD). After that, the silicon nitride film is etched back to be left only on either side of the gate.

Using the gate electrode 14 and sidewall insulation film 17 as masks, arsenic (As) is ion-implanted into the surface area of the silicon substrate 10 under the conditions that an acceleration voltage is 5 keV to 30 keV and a dose is 1×10¹⁵ cm⁻², thus forming second impurity diffusion regions (source/drain diffusion layers) 18 and 19. Then, the impurities in the first and second impurity diffusion regions 15, 16, 18 and 19 are activated by heat treatment, for example, for one second to one hundred minutes at a temperature of 750° C. to 1050° C. in the atmosphere of nitrogen.

After that, a silicon oxide film having a thickness of, e.g., 300 nm is deposited as an interlayer insulation film 20 on the entire surface of the resultant structure by CVD, and then a contact hole is formed in the interlayer insulation film 20 by anisotropic dry etching. Then, an aluminum film having a thickness of 800 nm and containing, e.g., 0.5% silicon and 0.5% copper is formed and patterned to form aluminum electrodes 21, 22 and 23. Finally, the resultant structure is heat-treated for fifteen minutes at a temperature of 450° C. in the atmosphere of nitrogen containing, e.g., 10% hydrogen. Thus, an n-channel MISFET as shown in FIG. 1 is completed.

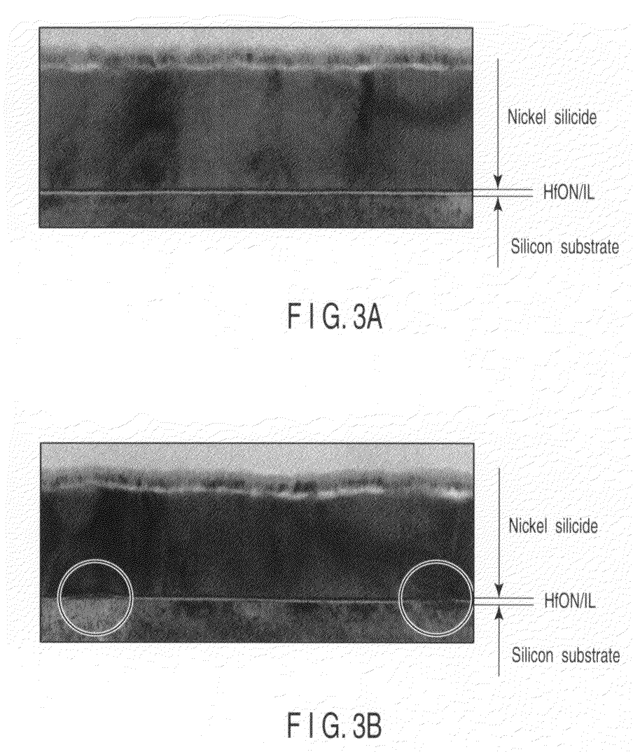

According to FIG. 3A, the interface layer 13b is formed by depositing a nitrogen incorporated hafnium oxide film as the high dielectric gate insulator 13a and then exposing it to a mixture of H₂ gas and O₂ gas at the pressure of 0.2 Torr. The time for heat treatment is one second. For comparison with FIG. 3A, FIG. 3B shows a cross sectional TEM photograph of a gate electrode section obtained by depositing a nitrogen incorporated hafnium oxide film on SiO₂ of about 1 nm and then annealing the film at a temperature of 1000° C.

It is apparent from FIG. 3A that the interfacial layer having a uniform thickness is formed at the interface between the nitrogen incorporated hafnium oxide film and the silicon substrate. In FIG. 3B showing that SiO₂ is formed before the nitrogen incorporated hafnium oxide film is deposited, a nickel silicide film serving as a gate electrode is short-circuited at a number of points (circled in FIG. 3B). It can be clearly seen from FIG. 3B that the irregularities of the interface between the nitrogen incorporated hafnium oxide film and the silicon substrate are greater than those in FIG. 3A. According to the first embodiment, a stable interfacial layer without a pin hole or the like can be formed in the interface between the nitrogen incorporated hafnium oxide film and the silicon substrate.

Temperature is important as a condition of heat treatment for forming the interfacial layer. When the temperature ranges from 800° C. to 1100° C., the above advantage can be obtained. Pressure is not so important and has only to range from 0.2 Torr to 200 Torr. Since the growing of the interfacial layer is saturated in short time, one second to ten seconds are enough as the processing time.

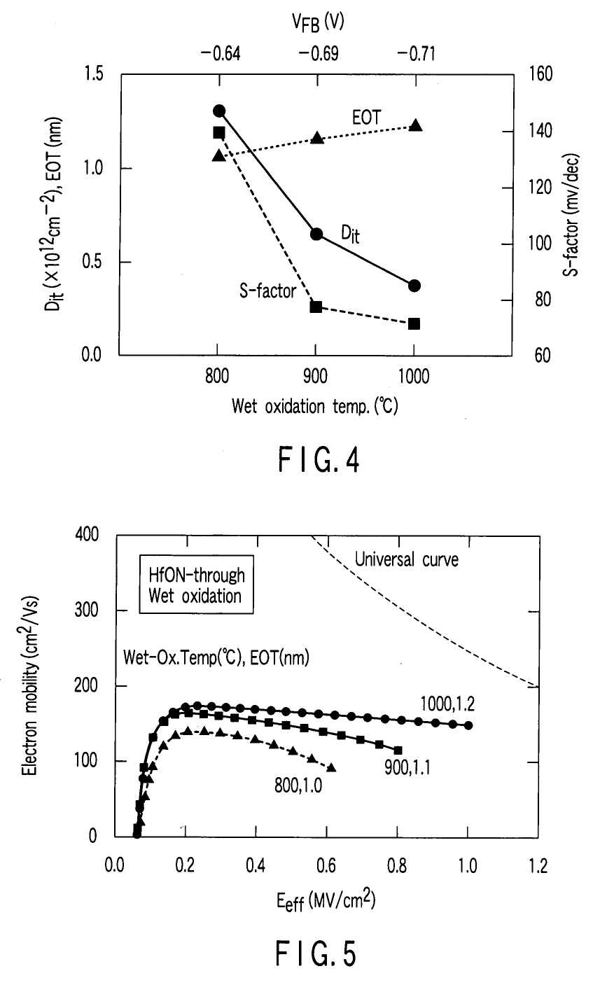

The stable interfacial layer of the first embodiment enables good transistor characteristics to be achieved. FIG. 4 shows variations of the interface state density Dit, S factor, and silicon-oxide-film equivalent oxide thickness (EOT) in an nMISFET when the temperature at which the substrate is exposed to a mixture of H₂ gas and O₂ gas to form the interfacial layer varies. It is found that the interface state density Dit and S factor are more improved as the temperature increases in FIG. 4. It is also found that the interface state density Dit is 0.7 or less and the S factor is 80 or less particularly when the temperature is 900° C. or higher in FIG. 4.

FIG. 5 shows the effective field dependency of electron mobility in the nMISFET when the above processing temperature varies. It is found that the electron mobility is more improved as the substrate is exposed to a mixture of H₂ gas and O₂ gas at a high temperature particularly in a high-field region in FIG. 5.

It is seen from the above that a high-performance transistor can be achieved by forming the high dielectric gate insulation film 13a and then exposing it to a mixture of H₂ gas and O₂ gas to form the interfacial layer 13b.

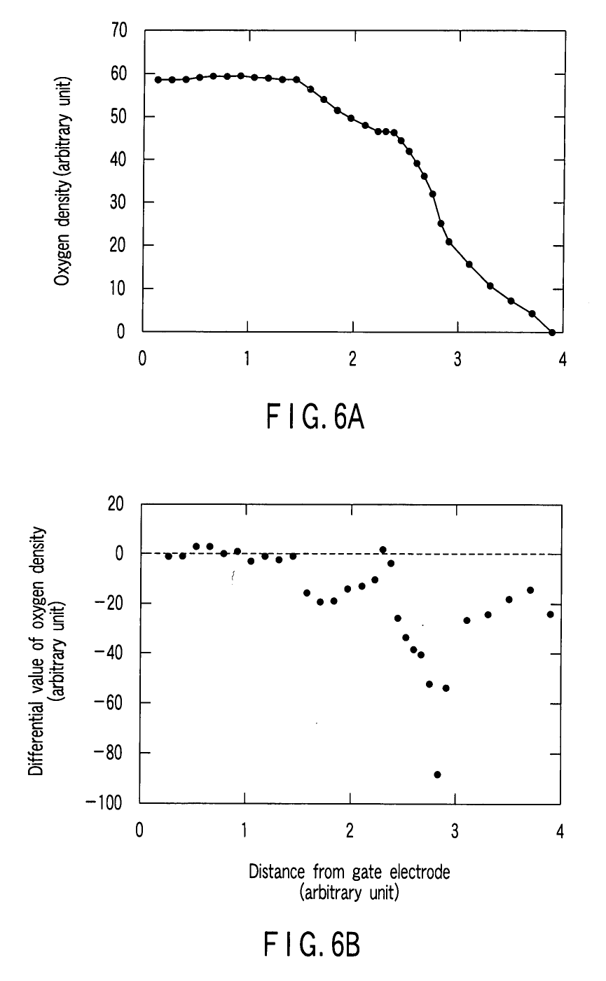

FIG. 6A shows a profile of oxygen density in the gate insulating film (including both the film 13a and layer 13b) formed by the method according to the first embodiment. In the first embodiment, the oxygen density does not decrease monotonously in the depth direction but increases at a certain depth. This is a phenomenon in which oxygen is actively introduced into the insulating film by wet oxidation heat treatment in a mixture of H₂ gas and O₂ gas, but it is not done more than a certain depth. The profile of FIG. 6A clearly differs from that of a prior art method wherein oxygen decreases monotonously from the surface of an insulating film toward the substrate.

FIG. 6B shows a differential value of the oxygen density shown in FIG. 6A. As shown in FIG. 6B, the differential value is 0 or more at a certain depth in the thickness direction of the gate insulating film. This phenomenon does not appear in the prior art method. The profile of oxygen density in the insulating film makes it possible to determine whether the gate insulating film is formed by the method of the first embodiment.

The inventors of the present invention conducted an experiment and ensured that in the MISFET manufactured by the foregoing method the above differential value was 0 or more in a region defined between a given distance from the substrate in the gate insulating film (including both the film 13a and layer 13b) and at a given distance from the gate electrode. More specifically, the inventors ensured that even though the conditions of heat treatment are changed, a differential value of 0 or more was present in the thickness direction of the gate insulation film in a region defined between a distance of 0.5 nm or more from the interface between the gate electrode and the gate insulating film and a distance of 0.3 nm or more from the interface between the substrate and the gate insulating film.

Conversely, the interfacial layer of the first embodiment can be formed if the density profile in the gate insulating film can be controlled such that a differential value of 0 or more is present in the thickness direction of the gate insulating film in a region defined between a distance of 0.5 nm or more from the interface between the gate electrode and the gate insulating film and a distance of 0.3 nm or more from the interface between the substrate and the gate insulating film.

According to the first embodiment, as described above, after the high dielectric gate insulating film 13a is formed, the silicon substrate 10 is exposed to a wet oxidation atmosphere containing a mixture of H₂ gas O₂ gas at a high temperature to thereby supply oxygen atoms to the interface between the film 13a and substrate 10. Thus, the interfacial layer 13b of high quality, which is made of a stable SiO₂ layer, can be formed between the film 13a and substrate 10 without causing damage to the process of forming the gate electrode. Consequently, a high-performance MISFET that inhibits electron mobility from deteriorating and lowers the interfacial state density can be achieved. In other words, the MISFET has the advantage obtained by using high dielectric constant materials for the gate insulating film.

In the first embodiment, the interface layer 13b is formed by heat treatment before the gate electrode 14 is formed. However, even though the interfacial layer 13b is formed after the gate electrode 14, the same advantage as described above can be obtained.

### Second Embodiment

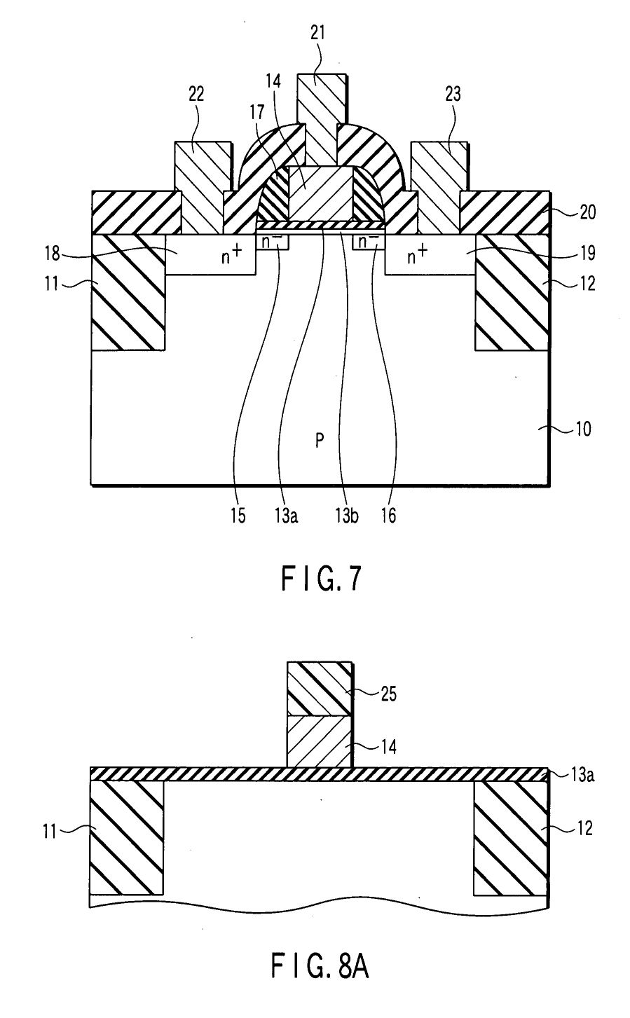

FIG. 7 is a schematic cross sectional view of the structure of an MIS semiconductor device according to a second embodiment of the present invention. The cross sectional view is taken in the direction of the channel length of the device. The same components as those of FIG. 1 are denoted by the same reference numerals.

As shown in FIG. 7, element isolation regions 11 and 12 are formed to a depth of about 0.6 μm in the surface area of a p-type silicon substrate 10 of face orientation (100) so as to surround an element forming region. An interfacial layer 13b having a thickness of e.g., 0.3 nm to 1 nm is formed on the element forming region as a gate insulating film, and a high dielectric gate insulating film 13a is deposited thereon. The interfacial layer 13b is formed by exposing the surface of the silicon substrate 10 to an atmosphere containing H₂ gas O₂ gas for wet oxide heat treatment after a gate sidewall insulating film (described later) is formed.

A nickel silicide film having a thickness of 80 nm is formed on the high dielectric gate insulating film 13a as a gate electrode 14. A sidewall insulating film 17 of, e.g., a silicon nitride film is formed on either side of the gate electrode 14. Source/drain extension layers 15 and 16 are formed in the surface area of the substrate and on the undersurface of the sidewall insulation film 17. Source/drain diffusion layers 18 and 19 are formed in the surface area of the substrate and outside the source/drain extension layers 15 and 16. A titanium silicide film (not shown) is formed on the surface of each of the source/drain diffusion layers 18 and 19.

A silicon oxide film 20 is formed as an interlayer insulating film on the entire surface of the substrate with the gate electrode 14 and sidewall insulating film 17 thereon. Contact holes are formed in the interlayer insulating n film 20 in positions corresponding to the gate electrode 14 and source/drain diffusion layers 18 and 19. Aluminum electrodes 21, 22 and 23 are so formed that they are connected to the gate electrode 14 and source/drain diffusion layers 18 and 19 via the contact holes.

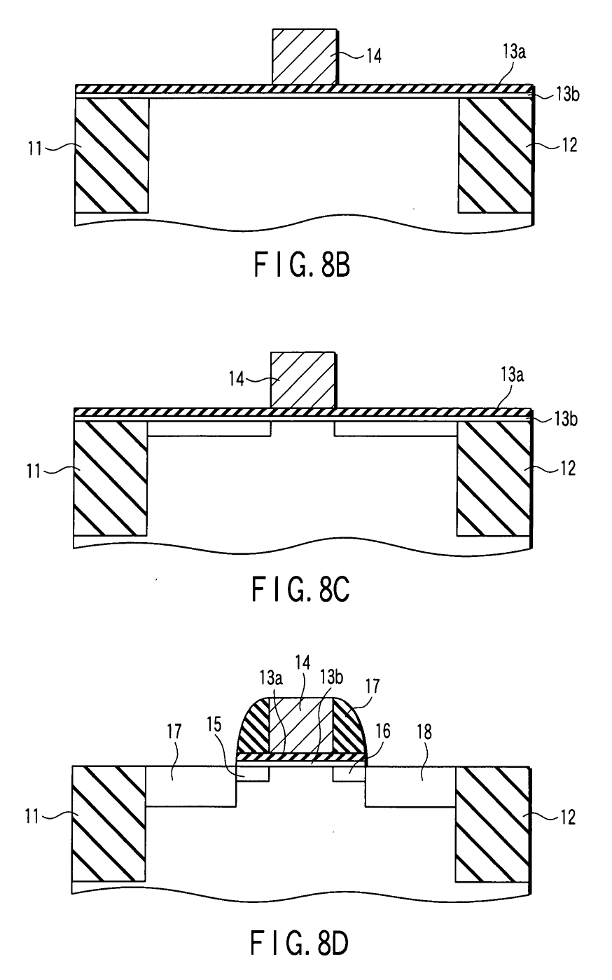

A process of manufacturing the semiconductor device according to the second embodiment will be described in FIGS. 8A to 8D.

As shown in FIG. 8A, a p-type silicon substrate 10 of, e.g., face orientation (100) is prepared, and element isolation regions 11 and 12 are formed to a depth of about 0.6 μm in the surface area of the p-type silicon substrate 10 by a normal shallow trench isolation (STI) method, as in the above first embodiment. After that, a diluted fluorinated acid process is performed in concentrations of, e.g., 1% and then a high dielectric gate insulating film 13a containing hafnium atoms, oxygen atoms and nitrogen atoms is deposited by the LL-D&A method using, e.g., NH₃ gas.

An amorphous silicon film having a thickness of 50 nm and a nickel film having a thickness of 30 nm are deposited on the gate insulating film 13a as the gate electrode 14 and then exposed to the atmosphere of nitrogen gas for ten seconds to one hour at a temperature of 400° C. to 700° C. to form a nickel silicide film. After that, using a resist mask 25, only the nickel silicide film is etched by reactive ion etching to form the gate electrode 14.

After the resist mask 25 is removed, wet oxidation is performed by exposing the substrate to the atmosphere containing H₂ gas and O₂ gas for one to ten seconds at a temperature of 800° C. to 1100° C. and at pressure of 0.2 Torr to 200 Torr, as shown in FIG. 8B. The interface layer 13b is therefore formed between the gate insulating film 13a and the silicon substrate 10.

And then, as shown in FIG. 8C, using the gate electrode 14 as a mask, arsenic (As) is ion-implanted into the surface area of the silicon substrate 10 under the conditions that an acceleration voltage is 1 keV to 10 keV and a dose is 1×10¹⁴ cm⁻². Thus, first diffusion regions (source/drain extension layers) 15 and 16 are formed.

As shown in FIG. 8D, a sidewall insulating film 17 of a silicon nitride film having a thickness of, e.g., 10 nm is formed on either side of the gate electrode 14. More specifically, a silicon nitride film having a thickness of, e.g., 10 nm is deposited on the entire surface of the substrate using LP-CVD and then etched back to be left only on either side of the gate. The gate insulating film 13a and interfacial layer 13b can be removed when the silicon nitride film is etched back. After the sidewall insulating film 17 is formed, the film 13a and layer 13b can selectively be removed using the film 17 as a mask.

Using the gate electrode 14 and sidewall insulation film 17 as masks, arsenic (As) is ion-implanted into the surface area of the silicon substrate 10 under the conditions that an acceleration voltage is 5 keV to 30 keV and a dose is 1×10¹⁵ cm⁻². Thus, second impurity diffusion regions (source/drain diffusion layers) 18 and 19 are formed. Then, the impurities in the second diffusion regions 18 and 19 are activated by heat treatment, for example, for one to one hundred minutes at a temperature of 750° C. to 1050° C. in the atmosphere of nitrogen.

After that, a silicon oxide film having a thickness of, e.g., 300 nm is deposited as an interlayer insulating film 20 on the entire surface of the resultant structure by CVD, and then a contact hole is formed in the interlayer insulation film 20 by anisotropic dry etching. Then, an aluminum film having a thickness of 800 nm and containing, e.g., 0.5% silicon and 0.5% copper is formed and patterned to form aluminum electrodes 21, 22 and 23. Finally, the resultant structure is heat-treated for fifteen minutes at a temperature of, e.g., 450° C. in the atmosphere of nitrogen containing, e.g., 10% hydrogen. Thus, an n-channel MISFET as shown in FIG. 7 is completed.

According to the second embodiment, as described above, after the high dielectric gate insulating film 13a is formed and the gate electrode 14 and sidewall insulating film 17 are formed, the silicon substrate 10 is exposed to a wet oxidation atmosphere containing a mixture of H₂ gas O₂ gas at a high temperature to thereby supply oxygen atoms to the interface between the film 13a and substrate 10. Thus, the interfacial layer 13b of high quality, which is made of a stable SiO₂ layer, can be formed between the film 13a and substrate 10 without causing damage to the process of forming the gate electrode. Consequently, the same advantage as that of the first embodiment can be obtained.

In the second embodiment, the interfacial layer 13b and high dielectric gate insulating film 13a remain on the source/drain extension layers 15 and 16, and the surfaces of the layers 15 and 16 are not subjected to etching damage in processing the gate. This is very advantageous to the layers 15 and 16 that are extremely shallow.

### (Modification)

The present invention is not limited to each of the first and second embodiments described above. More specifically, the embodiments are directed to a gate insulating film containing hafnium atoms, oxygen atoms, and nitrogen atoms; however, the present invention is not limited to such a gate insulating film. For example, the hafnium atoms can be replaced with lanthanum atoms, yttrium atoms, gadolinium atoms, or cesium atoms. The atmosphere of wet oxidation is not limited to the atmosphere of only H₂ gas and O₂ gas. The interfacial layer can be formed by heat treatment in the atmosphere of H₂ gas and O₂ gas to which N₂ gas is added. Furthermore, the same advantage as described above can be obtained even when the high dielectric gate insulating film contains no nitrogen atoms.

The first and second embodiments are directed to the n-channel MISFET. Needless to say, the present invention can be applied to a p-channel MISFET. The conditions for forming the interface layer, such as temperature, pressure, and processing time, can be varied appropriately in accordance with the specifications of the MISFET. The substrate is not limited to the silicon substrate, but semiconductor substrates of different types can be used.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended and their equivalents.

What is claimed is:

1. A method of manufacturing an MIS semiconductor device, comprising:
forming a high dielectric film as a gate insulator on a semiconductor substrate of a first conductivity type;
heat-treating the semiconductor substrate in ambient with hydrogen and oxygen gases to form an interfacial layer between the semiconductor substrate and the high dielectric film;
forming a conductive film on the high dielectric film after the interfacial layer is formed;
processing the conductive film in a gate pattern to form a gate electrode; and
doping the semiconductor substrate with impurities of a second conductivity type using the gate electrode as a mask to form source/drain regions.

2. The method according to claim 1, wherein the heat-treating includes heat-treating the semiconductor substrate at a temperature ranging from 800° C. to 1100° C. in ambient with hydrogen and oxygen gases.

3. The method according to claim 2, wherein the heat-treating includes heat-treating the semiconductor substrate at a temperature of 900° C. or higher in ambient with hydrogen and oxygen gases.

4. The method according to claim 1, wherein forming the high dielectric film as the gate insulator includes forming the gate insulating film with a high dielectric film containing hafnium atoms, oxygen atoms, and nitrogen atoms.

5. A method of manufacturing an MIS semiconductor device, comprising:
forming a high dielectric film as a gate insulator on a semiconductor substrate of a first conductivity type;
forming a conductive film on the high dielectric film;
processing the conductive film in a gate pattern to form a gate electrode;
heat-treating the semiconductor substrate with the gate electrode in ambient with hydrogen and oxygen gases to form an interfacial layer between the semiconductor substrate and the high dielectric film; and
doping the semiconductor substrate with impurities of a second conductivity type using the gate electrode as a mask, after the interface layer is formed to form source/drain regions.

6. The method according to claim 5, wherein the heat-treating includes heat-treating the semiconductor substrate at a temperature ranging from 800° C. to 1100° C. in ambient with hydrogen and oxygen gases.

7. The method according to claim 6, wherein the heat-treating includes heat-treating the semiconductor substrate at a temperature of 900° C. or higher in ambient with hydrogen and oxygen gases.

8. The method according to claim 5, wherein forming the high dielectric film as the gate insulator includes forming the gate insulating film with a high dielectric film containing hafnium atoms, oxygen atoms, and nitrogen atoms.

9. A method of manufacturing an MIS semiconductor device, comprising:
forming a high dielectric film as a gate insulation film on a semiconductor substrate of a first conductivity type;
forming a conductive film on the high dielectric film;
processing the conductive film in a gate pattern to form a gate electrode;
forming a sidewall insulating film on either side of the gate electrode;
heat-treating the semiconductor substrate with the gate electrode and the sidewall insulating film in ambient with hydrogen and oxygen gases to form an interfacial layer between the semiconductor substrate and the high dielectric film; and
doping the semiconductor substrate with impurities of a second conductivity type using the gate electrode and the sidewall insulating film as a mask, after the interfacial layer is formed to form source/drain regions.

10. The method according to claim 9, wherein the heat-treating includes heat-treating the semiconductor substrate at a temperature ranging from 800° C. to 1100° C. in ambient with hydrogen and oxygen gases.

11. The method according to claim 10, wherein the heat-treating includes heat-treating the semiconductor substrate is heat-treated at a temperature of 900° C. or higher in ambient with hydrogen and oxygen gases.

12. The method according to claim 9, wherein forming the high dielectric film as the gate insulator includes forming the gate insulating film with a high dielectric film containing hafnium atoms, oxygen atoms, and nitrogen atoms.

13. An MIS semiconductor device comprising:
a semiconductor substrate of a first conductivity type;
a gate electrode formed on the semiconductor substrate;
a high dielectric gate insulating film formed between the gate electrode and the semiconductor and having an oxygen density profile controlled such that the gate insulating film contains at least a region having zero or more differential value of oxygen density with respect to its thickness direction, the region existing within an area defined by a distance of 0.5 nm or more from a first interface toward a second interface and a distance of 0.3 nm or more from the second interface toward the first interface, and the first interface being an interface between the gate electrode and the gate insulating film and the second interface being an interface between the semiconductor substrate and the gate insulating film to the region; and
source/drain regions of a second conductivity type, which are formed on a surface of the semiconductor substrate and between which a channel region is formed under the gate electrode.

14. The device according to claim 13, wherein the gate insulating film is formed of a high dielectric film containing hafnium atoms, oxygen atoms, and nitrogen atoms.

15. The device according to claim 13, wherein the semiconductor substrate is formed of a semiconductor substrate heat-treated at a temperature ranging from 800° C. to 1100° C. in ambient with hydrogen and oxygen gases.

16. The method according to claim 15, wherein the semiconductor substrate is formed of a semiconductor substrate heat-treated at a temperature of 900° C. or higher in ambient with hydrogen and oxygen gases.
